(19) United States
(12) Patent Application Publication
(10) Pub. No.: US 2008/0057699 A1
(43) Pub. Date: Mar. 6, 2008

(54) Method for manufacturing semiconductor device

(75) Inventor: Dong Ki Jeon, Gangneung-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/893,909

(22) Filed: Aug. 17, 2007

(30) Foreign Application Priority Data
Aug. 29, 2006 (KR) 10-2006-0082450

(51) Int. Cl. H01L 21/4763

(52) U.S. Cl. 438/620; 257/E21.597

(57) ABSTRACT

Provided is a method for manufacturing a semiconductor device. In the method, an insulating layer is formed on a substrate. A via hole and a trench are formed in the insulating layer. A TiN layer may be formed in the via hole and the trench by physical vapor deposition (PVD). A diffusion barrier layer comprising a TiSiN layer is formed on the TiN layer by PVD. A seed layer (preferably comprising Cu) is formed on the diffusion barrier layer, and a via plug and a metal line are formed on the (Cu) seed layer in the via hole and the trench.

### CROSS-REFERENCE TO RELATED APPLICATIONS

The present application claims the benefit under 35 U.S.C. § 119 of Korean Patent Application No. 10-2006-0082450, filed Aug. 29, 2006, which is hereby incorporated by reference in its entirety.

### BACKGROUND

Cu is used for a metal line of a semiconductor device, and Ta may be used for an adhesive layer and/or a diffusion barrier layer of a Cu line. However, since Ta is presently about ten times more expensive than Ti, Ta increases the manufacturing costs in a semiconductor process.

Also, according to the related art, Ta provides poor adhesion with respect to an underlying insulating layer (oxide layer).

### SUMMARY

Embodiments of the invention provide a method for manufacturing a semiconductor device having an effective Cu diffusion barrier layer by providing a method of forming TiSiN that overcomes limitations of the related art.

In one embodiment, a method for manufacturing a semiconductor device includes: forming an insulating layer on a substrate; forming a via hole and a trench in the insulating layer; forming a TiN layer in the via hole and the trench by physical vapor deposition (PVD); forming a diffusion barrier layer comprising a TiSiN layer on the TiN layer by physical vapor deposition (PVD); forming a (Cu) seed layer on the diffusion barrier layer; and forming a via plug and a metal line on the (Cu) seed layer in the via hole and the trench.

In another embodiment, the method includes: forming an insulating layer on a substrate; forming a via hole and a trench in the insulating layer; forming a diffusion barrier layer comprising a TiSiN layer in the via hole and the trench by physical vapor deposition (PVD); forming a (Cu) seed layer on the diffusion barrier layer; and forming a via plug and a metal line on the (Cu) seed layer in the via hole and the trench.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view explaining a method for manufacturing a semiconductor device according to an embodiment of the invention.

FIG. 2 is a view illustrating a recipe of a method for manufacturing a semiconductor device according to an embodiment of the invention.

FIG. 3 is a view illustrating a recipe of a method for manufacturing a semiconductor device according to another embodiment of the invention.

### DETAILED DESCRIPTION OF THE EMBODIMENTS

A method for manufacturing a semiconductor device will be described according to various embodiments with reference to the accompanying drawings. In the description of the various embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

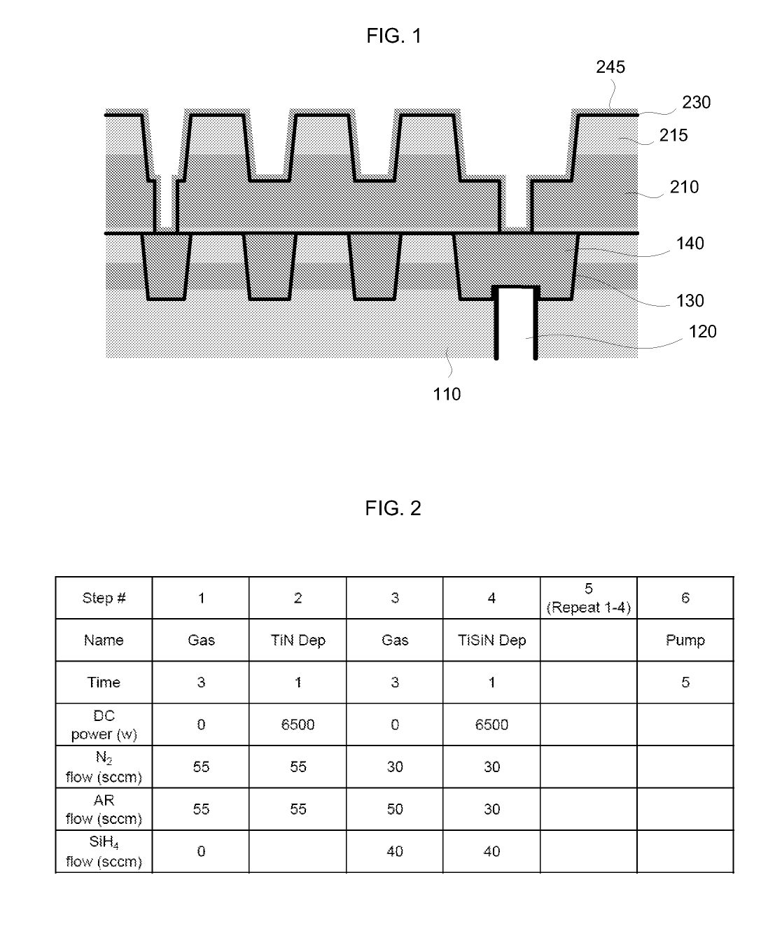

FIG. 1 is a cross-sectional view explaining a method for manufacturing a semiconductor device according to an embodiment. The method for manufacturing the semiconductor device according to an embodiment will be described below.

First, a first diffusion barrier layer 130 is formed in a first interlayer insulating layer 110 (which may include one or more sublayers of insulating material, such as silicon dioxide [which may be undoped or doped with fluorine or boron and/or phosphorous], and which may be include one or more etch stop layers [comprising, e.g., silicon nitride], above or below the stack of oxide sublayers or between two oxide sublayers), and a first via plug 120 (e.g., comprising tungsten or copper) and a first metal line 140 (e.g., comprising aluminum or copper) are formed as illustrated in FIG. 1.

A second interlayer insulating layer 210 (e.g., comprising a fluorinated silicate glass [FSG] or other low-k dielectric) and a third interlayer insulating layer 215 (e.g., comprising an undoped silicate glass [USG] or plasma-assisted silicon dioxide [e.g., a so-called “plasma silane” and/or “TEOS” based silicon dioxide) are formed on a substrate including the first metal line 140 (and optionally an etch stop [e.g., silicon nitride] layer under the second interlayer insulating layer 210). A via hole and a trench are formed in the second and third insulating layers 210 and 215. At this point, the via hole can be formed first and the trench can be formed later, or the trench can be formed first and the via hole can be formed later.

A second diffusion barrier layer 230 is formed in the via hole and the trench, a seed layer 245 (preferably comprising Cu) is formed on the second diffusion barrier layer 230, a second via plug (not shown) and a second metal line (not shown) are formed in the via hole and the trench using electroplating (or alternatively, electroless plating). The seed layer (Cu, Ru, Pd or other seed layer) may be formed by PVD or chemical vapor deposition (CVD).

According to an embodiment, the second diffusion barrier layer 230 can be formed using a TiSiN layer by physical vapor deposition (PVD). In a method for manufacturing a semiconductor device according to the embodiment, a diffusion barrier layer for subsequently deposited Cu can be formed at lower costs than that of the case of Ta. Also, according to the embodiment, a diffusion barrier layer for subsequently deposited Cu having smaller film stress that of the case of Ta can be formed. Also, according to an embodiment, a diffusion barrier layer where a Cu seed layer is easy to form can be formed.

Hereinafter, a detailed embodiment is described.

### Embodiment 1

FIG. 2 is a table illustrating a recipe of a method for manufacturing a semiconductor device according to an embodiment of the invention.

First, in step 1, a substrate including the via hole and the trench is loaded in a PVD chamber, and 55 sccm of N₂ gas and an Ar gas are supplied, respectively, for about 3 seconds. Of course, the flow rates of the N₂ gas and Ar gas may be independently varied in the range of from 10 to 100 sccm, and/or at ratios of from 5:1 to 1:5 (e.g., from 3:1 to 1:3), as may be desired.

Next, in step 2, a Ti target material (not shown) is loaded in the chamber (if not already present in the chamber), and power is applied to the chamber to sputter Ti from the target and form a thin TiN layer in the via hole and the trench of the substrate. At this point, the process is performed for about 1-2 seconds (in one embodiment) to form a thin TiN layer of about 13-16 Å.

Next, in step 3, N₂, Ar, and SiH₄ gases are supplied to the substrate including the TiN layer at flow rates of 30, 50, and 40 sccm for about 3 seconds, respectively. Of course, the flow rates of each of the N₂ gas, Ar gas and SiH₄ gas may be independently varied in the range of from 10 to 100 sccm, and/or at ratios of from 10:1 to 1:10 (e.g., from 5:1 to 1:5) with respect to the total of the other gases, as may be desired.

Next, in step 4, the Ti target material is used and power is applied to form a thin TiSiN layer on the substrate including the TiN layer. At this point, the process is performed for about 1-2 seconds to form a thin TiSiN layer of about 13-16 Å. One or more of the flow rates of the N₂ gas, Ar gas and SiH₄ gas may be varied within the range and/or at ratio described above in step 4, when the power is applied.

Next, in step 5, the steps 1 to 4 are repeated to obtain additional TiN and TiSiN layers of desired composition and thickness.

For example, since a speed of forming TiSiN is about 10-15 Å per second according to an exemplary recipe, repeating the process about ten times can form a diffusion barrier layer comprising a plurality of the TiSiN layers having a total thickness of about 120-140 Å. When the diffusion barrier layer has a thickness of about 120 Å or less, it may be too thin and not sufficient as a diffusion barrier layer. When the diffusion barrier layer has a thickness exceeding 140 Å, it may be too thick, so that subsequent contact with the via hole or the trench may be limited in some respect.

To control the depositing speed, direct current (DC) power applied to a target material can be controlled. Also, according to an embodiment, the depositing speed of Ti and N can be controlled using an amount or flow of the Ar gas.

For example, the compositions or atomic percentages of Ti and N can be controlled using the characteristics that deposition of Ti increases as the Ar gas flow increases, and deposition of N increases as the Ar gas flow decreases. Also, deposition of Si (e.g., its atomic percentage) can be controlled using a characteristic that deposition of Si increases as the flow of SiH₄ increases. Consequently, a predetermined atomic ratio of Ti:Si:N (e.g., TiSiN of desired composition) can be obtained by controlling the amount or flow rates of the Ar and SiH₄. In one exemplary embodiment, with a TiN layer formed, a power of about 6500 W is applied under conditions of flowing of about 30 sccm of N₂, about 30 sccm of Ar, and about 40 sccm of SiH₄ to obtain a TiSiN layer having composition of Ti:Si:N=1:1:1. Also, the TiSiN composition (e.g., a predetermined atomic ratio of Ti:Si:N) and/or the thickness of the TiSiN layer can be controlled by controlling the operation times for forming the TiN layer and for forming the TiSiN layer.

Next, in step 6, the chamber is pumped, and the substrate on which the diffusion barrier layer has been formed is unloaded to complete the process.

### Second Embodiment

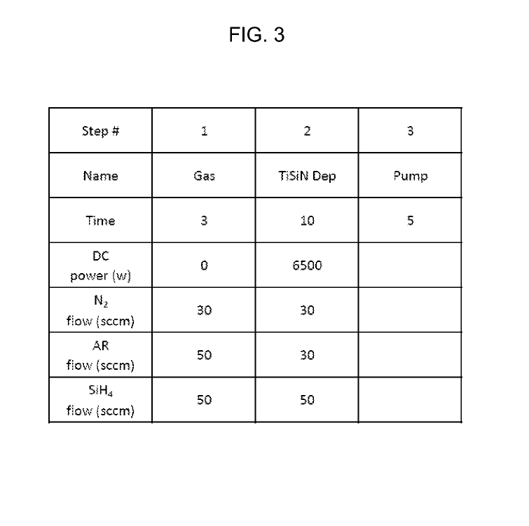

FIG. 3 is a view illustrating a recipe of a method for manufacturing a semiconductor device according to another embodiment.

First, in step 1 of FIG. 3, a substrate having a via hole and a trench in an exposed insulating layer is loaded in a PVD chamber, and N₂, Ar, and SiH₄ gases are supplied in amounts or at rates of 30, 50, and 50 sccm, respectively, for about 3 seconds. As for the first embodiment, the flow rates of each of the N₂ gas, Ar gas and SiH₄ gas may be independently varied in the range of from 10 to 100 sccm, and/or at ratios of from 10:1 to 1:10 (e.g., from 5:1 to 1:5) with respect to the total of the other gases, as may be desired.

Next, in step 2, a Ti target material is used and power is applied to sputter Ti from the target and form a thin TiSiN layer on the substrate. At this point, the process can be performed while N₂, Ar, and SiH₄ gases are supplied in amounts or at rates of 30, 30, and 50 sccm. Also, the process may be performed for about 10-12 seconds to form a TiSiN layer of about 120-140 Å in thickness.

For example, since a speed of forming TiSiN is about 10-15 Å per second according to a recipe of the second embodiment, a processing time of about ten seconds should be sufficient to form a diffusion barrier layer (e.g., consisting essentially of the TiSiN layer) having a thickness of about 120-140 Å. When the diffusion barrier layer (or the TiSiN layer has a thickness of less than about 120 Å, it may be too thin and/or not sufficient as a diffusion barrier layer. When the diffusion barrier layer (or the TiSiN layer) has a thickness exceeding 140 Å, it may be too thick, so that subsequent contact with the via hole and/or the trench may be limited.

Also, to control the depositing speed, DC power applied to a target material can be controlled. For example, the DC power may be from 1000 W to 12,000 W (and in various embodiments, from 2000 W to 10,000 W, or any range of values therein). Such variations for the DC power may also be applied to the first embodiment above.

Also, according to another embodiment, the depositing speed of Ti and N can be controlled using an amount of the Ar gas. For example, the compositions of Ti and N can be controlled using the characteristics that deposition of Ti increases when the Ar gas flow increases, and deposition of N increases when the Ar gas flow decreases. Also, the deposition and/or composition of Si can be controlled using a characteristic that deposition of Si increases when the flow of SiH₄ increases. Consequently, Ti:Si:N of desired composition can be obtained by controlling the amount or flow of the Ar and SiH₄ gases.

In another embodiment, a power of about 6500 W is applied under conditions of flowing of about 30 sccm of N₂, about 30 sccm of Ar, and about 50 sccm of SiH₄ to obtain a TiSiN layer having Ti:Si:N composition=1:1:1.

As described above, the method for manufacturing a semiconductor device according to an embodiment can form a diffusion barrier layer for Cu contacts and metal lines at low costs. Also, according to an embodiment, a diffusion barrier layer having better adhesion with an interlayer insulating layer than that of Ta can be obtained. Also, according to an embodiment, since deposition times for the diffusion barrier layer may be short, high productivity can be achieved. Also, according to an embodiment, since a diffusion barrier layer is deposited using plasma (e.g., PVD), it can be deposited at a relatively low temperature, and the thickness and composition of a TiSiN layer can be controlled by time only, so that efficiency in the manufacturing process may improve.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, the method comprising:
forming an insulating layer on a substrate;
forming a via hole and a trench in the insulating layer;
forming a first TiN layer in the via hole and the trench by physical vapor deposition (PVD);
forming a diffusion barrier layer comprising a first TiSiN layer on the first TiN layer by physical vapor deposition (PVD);
forming a seed layer on the diffusion barrier layer; and
forming a via plug and a metal line on the seed layer in the via hole and the trench.

2. The method according to claim 1, wherein further comprising forming a second TiN layer by physical vapor deposition and forming a second TiSiN layer on the second TiN layer by physical vapor deposition.

3. The method according to claim 2, further comprising successively forming an additional TiN layer on an exposed TiSiN layer and an additional TiSiN layer on an exposed TiN layer, then repeating the successively forming steps seven times.

4. The method according to claim 1, wherein forming the TiN layer comprises depositing the TiN layer in an atmosphere of N₂ and Ar for a length of time of from 1 to 2 seconds.

5. The method according to claim 1, wherein forming the TiSiN layer comprises depositing the TiSiN layer in an atmosphere of N₂, Ar, and SiH₄ for a length of time of from 1 to 2 seconds.

6. The method according to claim 2, wherein depositing the TiN layer comprises sputtering Ti in said atmosphere of N₂ and Ar.

7. The method according to claim 3, wherein depositing the TiSiN layer comprises sputtering Ti in said atmosphere of N₂, Ar, and SiH₄.

8. The method according to claim 2, wherein forming the TiSiN layer comprises depositing the TiSiN layer in an atmosphere of N₂, Ar, and SiH₄ for a length of time of from 1 to 2 seconds.

9. The method according to claim 6, wherein forming the diffusion barrier layer comprises controlling flows of Ar and SiH₄ such that an atomic percentage of Ti increases as the flow of Ar increases, an atomic percentage of N increases as the flow of Ar decreases, and an atomic percentage of Si increases as the flow of SiH₄ increases.

10. The method according to claim 1, wherein forming the TiSiN layer comprises controlling deposition times of forming the TiN layer and forming the TiSiN layer.

11. The method according to claim 1, wherein forming the seed layer comprises depositing a Cu seed layer by PVD or chemical vapor deposition (CVD).

12. A method for manufacturing a semiconductor device, the method comprising:
forming an insulating layer on a substrate;
forming a via hole and a trench in the insulating layer;
forming a diffusion barrier layer comprising a TiSiN layer in the via hole and the trench by physical vapor deposition (PVD);
forming a seed layer on the diffusion barrier layer; and
forming a via plug and a metal line on the seed layer in the via hole and the trench.

13. The method according to claim 12, wherein the TiSiN layer has a thickness of 120-140 Å.

14. The method according to claim 12, wherein forming the TiSiN layer comprises depositing the TiSiN layer for a length of time of from 10 to 15 seconds.

15. The method according to claim 12, wherein the TiSiN layer comprises sputtering Ti from a Ti target material in an atmosphere comprising Ar, N₂, and SiH₄.

16. The method according to claim 11, wherein forming the diffusion barrier layer comprises controlling flows of Ar and SiH₄ such that an atomic percentage of Ti increases as the flow of Ar increases, an atomic percentage of N increases as the flow of Ar decreases, and an atomic percentage of Si increases as the flow of SiH₄ increases.

17. The method according to claim 12, wherein forming the seed layer comprises depositing a Cu seed layer by PVD or chemical vapor deposition (CVD).

18. The method according to claim 17, wherein forming the via plug and the metal line comprises electroplating or electrolessly plating Cu the Cu seed layer.

19. The method according to claim 12, wherein forming the via plug and the metal line comprises electroplating or electrolessly plating Cu the seed layer.

20. The method according to claim 12, wherein the diffusion barrier layer consists essentially of the TiSiN layer.
